(19) United States
(12) Patent Application Publication
(10) Pub. No.: US 2023/0417383 A1
(43) Pub. Date: Dec. 28, 2023

(54) LOW PROFILE EMERGENCY BATTERY-DRIVER ENCLOSURE

(71) Applicant: ABL IP Holding LLC, Atlanta, GA (US)

(72) Inventors: Dileep Kumar Kallamthottathil, Snellville, GA (US); Gunjan P. Patel, Alpharetta, GA (US)

(21) Appl. No.: 18/206,327

(22) Filed: Jun. 6, 2023

Related U.S. Application Data
(60) Provisional application No. 63/354,340, filed on Jun. 22, 2022.

(51) Int. Cl. F21S 9/02; F21V 23/00; H05K 5/02; H05K 5/00

(52) U.S. Cl. CPC F21S 9/022; F21V 23/008; H05K 5/0204; H05K 5/0013

(57) ABSTRACT

A battery-driver enclosure for a light fixture includes a first member and a second member. The first member and the second member together define the battery-driver enclosure, and the first member and the second member overlap at non-adjacent corners of the enclosure. A method of assembling a battery-driver enclosure includes engaging the first member with the second member to form the battery-driver enclosure and such that the first member and the second member overlap at non-adjacent corners of the battery-driver enclosure.

### REFERENCE TO RELATED APPLICATION

This application claims the benefit of U.S. Provisional Patent Application No. 63/354,340, filed on Jun. 22, 2022, and entitled LOW PROFILE EMERGENCY BATTERY-DRIVER ENCLOSURE, the content of which is hereby incorporated by reference in its entirety.

### FIELD OF THE INVENTION

This application relates to lighting systems in general, and more particularly to emergency battery and/or driver enclosures and light fixtures incorporating the same.

### BACKGROUND

Lighting systems, including those utilizing light-emitting diode (LED) light sources, may include emergency (or back-up) power features operating independently from a primary power source. Such emergency power features may include a battery and a driver to respectively power and control the lighting system in the event of failure of the primary power source (such as due to a power outage). As such, emergency power features may supply short-term power to the lighting system to provide a variety of emergency-related lighting, including evacuation lights, emergency signs, and other safety-providing lighting. Emergency power features are often included in close proximity to the light sources, and optionally may be housed within or as part of the housing of the lighting system. Due to existing housing-lid methodologies of construction, existing emergency drivers have a larger cross section and may be difficult to accommodate inside the housing of the lighting system.

### SUMMARY

Described herein are emergency power features with reduced overall size requirements. In certain embodiments, the emergency power features include a low profile emergency battery-driver enclosure. The features described herein may be beneficial to minimize the space occupied by such emergency features, particularly for modern lighting systems that may have low-profile and minimized lighting features.

### BRIEF DESCRIPTION OF THE DRAWINGS

FIGS. 1A-B illustrate conventional enclosures for emergency power features for light fixtures.

FIG. 2 is an exploded view of a driver enclosure according to embodiments.

FIG. 3 is a sectional view of the driver enclosure of FIG. 2.

FIG. 4 is a perspective view of a first member of the driver enclosure of FIG. 2.

FIG. 5 is a perspective view of a portion of the first member of the driver enclosure of FIG. 2.

FIG. 6 is a top view of the portion of the first member of the driver enclosure of FIG. 2.

FIG. 7 is a side view of the portion of the first member of the driver enclosure of FIG. 2.

FIG. 8 is a perspective view of a second member of the driver enclosure of FIG. 2.

FIG. 9 is a perspective view of a portion of the second member of the driver enclosure of FIG. 2.

FIG. 10 is a top view of the portion of the second member of the driver enclosure of FIG. 2.

FIG. 11 is a side view of the portion of the second member of the driver enclosure of FIG. 2.

FIG. 12 illustrates a step of assembling the driver enclosure of FIG. 2.

FIGS. 13A-B illustrate steps of assembling the driver enclosure of FIG. 2.

FIG. 14 illustrates a step of assembling the driver enclosure of FIG. 2.

FIG. 15 illustrates a step of assembling the driver enclosure of FIG. 2.

FIG. 16 is a perspective, sectional view of a portion of the driver enclosure of FIG. 2.

FIG. 17 is a perspective, sectional view of a portion of the driver enclosure of FIG. 2.

FIG. 18 is a perspective view of a portion of the driver enclosure of FIG. 2.

FIG. 19 is a perspective view of a portion of the driver enclosure of FIG. 2.

### DETAILED DESCRIPTION

Described herein are devices and systems for a driver enclosure (or battery-driver enclosure) for enclosing a battery and driver, and methods of use of the same. The driver enclosures described herein may be utilized in a lighting system, such as but not limited to a lighting system utilizing LED light sources. In certain embodiments, the driver enclosures described herein have reduced overall external dimensions without sacrificing usable space provided within the enclosure. The driver enclosures described herein may include an interlocking structure without and/or omitting a large overlap between a lid component and a base structure. In such cases, the interlocking structure may provide uniform or substantially uniform external dimensions as well as uniform or substantially uniform internal dimensions. In various embodiments, the driver enclosures described herein include a first member and a second member, and the first member and the second member overlap at non-adjacent (e.g., diagonal) corners of the enclosure. The overlap and interlocking of the first member and the second member at non-adjacent corners may optimize the space required for overlapping, thereby reducing changes in internal volume and/or external widths of the enclosure compared to traditional enclosures. Various other benefits and advantages may be realized with the systems and methods provided herein, and the aforementioned advantages should not be considered limiting.

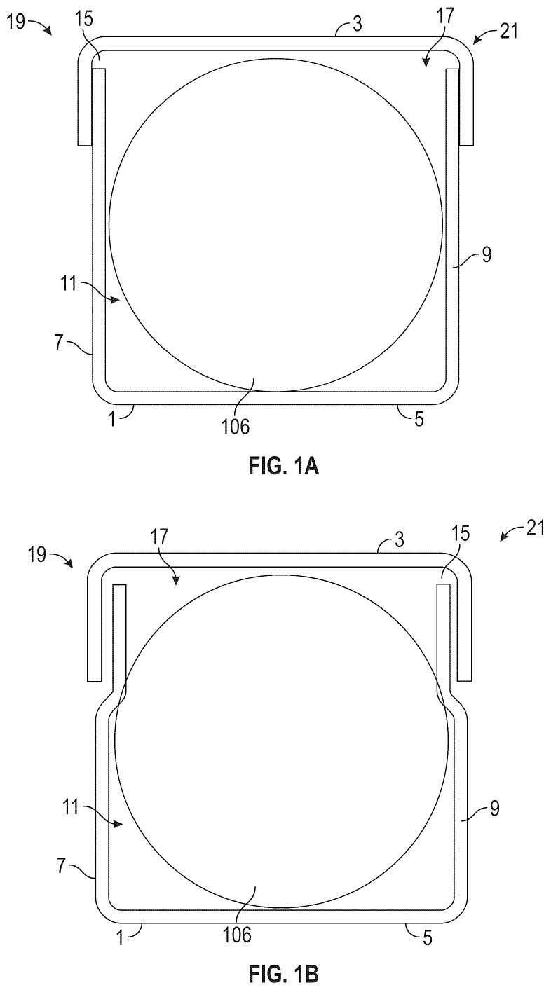

Referring to FIGS. 1A and 1B, conventional enclosures for emergency power features have included a housing 1 and a lid 3. The housing 1 generally includes a base 5 and opposing side walls 7, 9 that define a receiving area 11 for a battery 106 and/or a driver. A top end 15 of the housing 1 opposite from the base 5 defines an opening 17, and the battery 106 and/or driver may be positioned into the receiving area 11 through the opening 17. To fully assemble the enclosure, the lid 3 is provided on the top end 15 of the housing 1 such that the lid 3 covers the opening 17 and overlaps the side walls 7, 9 at the top end 15. As illustrated in FIGS. 1A and 1B, conventional enclosures may have a generally square or rectangular cross-section, and the overlap of conventional lids 3 occurs at adjacent corners 19, 21 of the enclosure (e.g., the top left corner 19 and the top right corner 21 of the enclosure viewed in cross-section are formed by the lid overlapping the side walls). Such conventional attachment of the lid 3 with the housing 1 suffers from several limitations. For example, referring to FIG. 1A, if the side walls 7, 9 of the housing 1 are straight or planar, the overlapping lid 3 increases the overall width of the enclosure. The overlapping of the lid 3 and the housing 1 creates space losses within a light fixture (e.g., it must accommodate the increased width). Conversely, and referring to FIG. 1B, the side walls 7, 9 may be tapered inwards to minimize an increase in outer width of the enclosure due to the lid 3. However, in such embodiments, the volume of the receiving area 11 is reduced, which may interfere with the battery 106 and/or limit the batteries and/or drivers that could be placed within the receiving area 11.

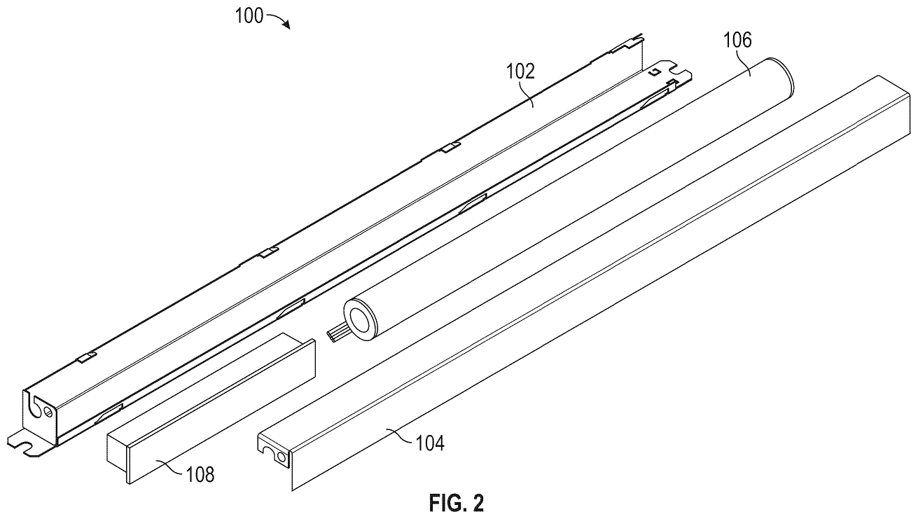

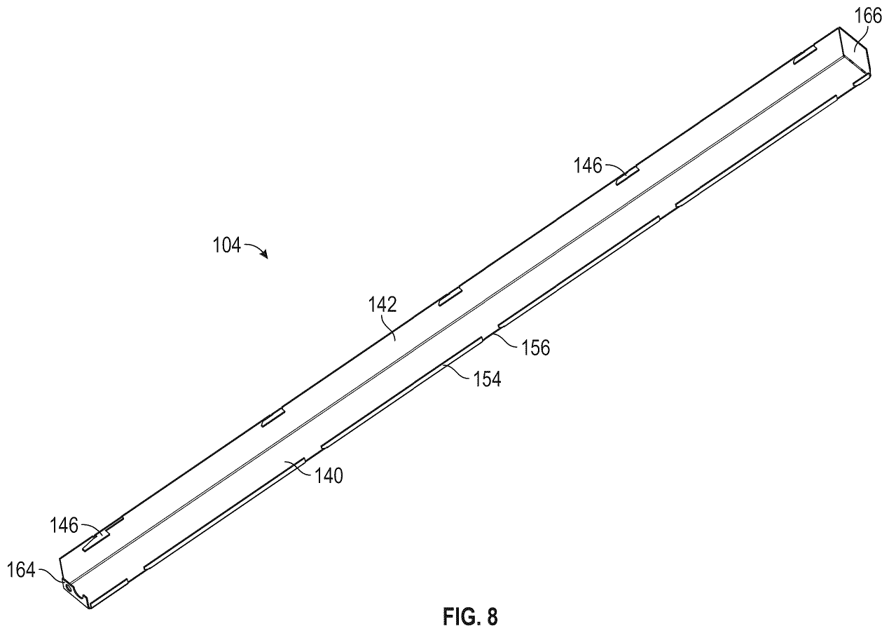

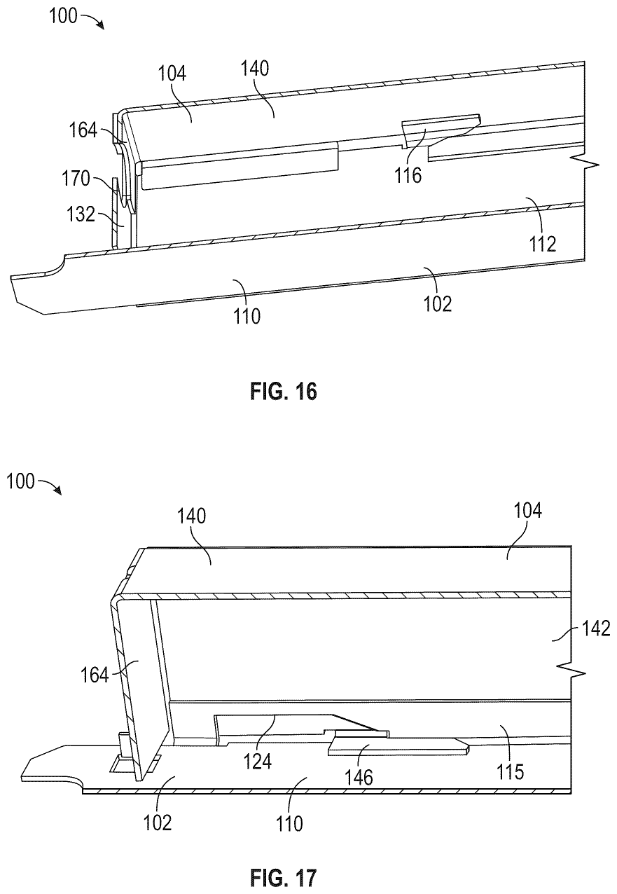

FIGS. 2-18 illustrate a driver enclosure 100 according to embodiments. The driver enclosure 100 includes a first member 102 and a second member 104. As discussed in detail below, the first member 102 and the second member 104 may interlock to form the driver enclosure 100, which may house a battery 106 and/or a driver 108 as emergency or back-up features.

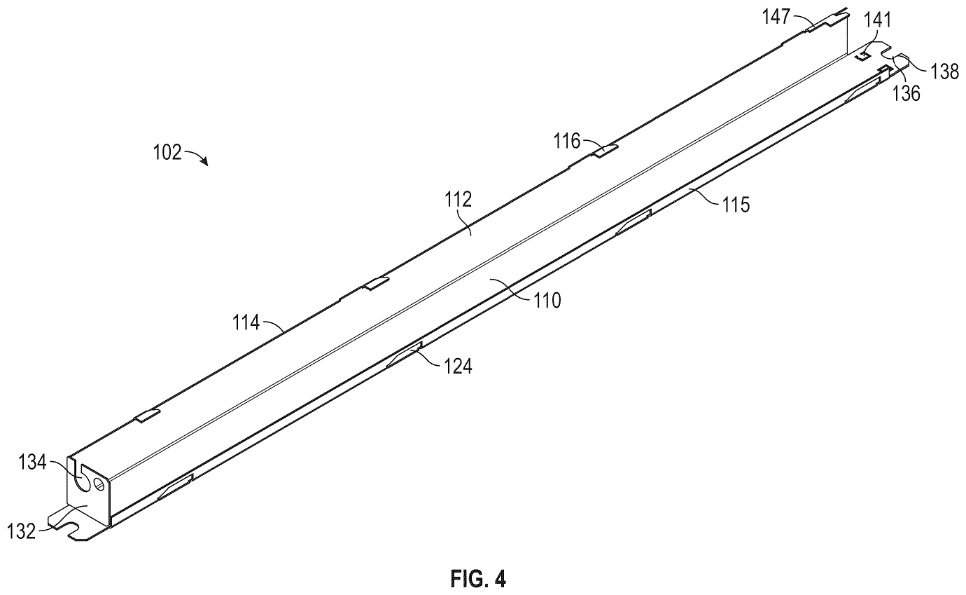

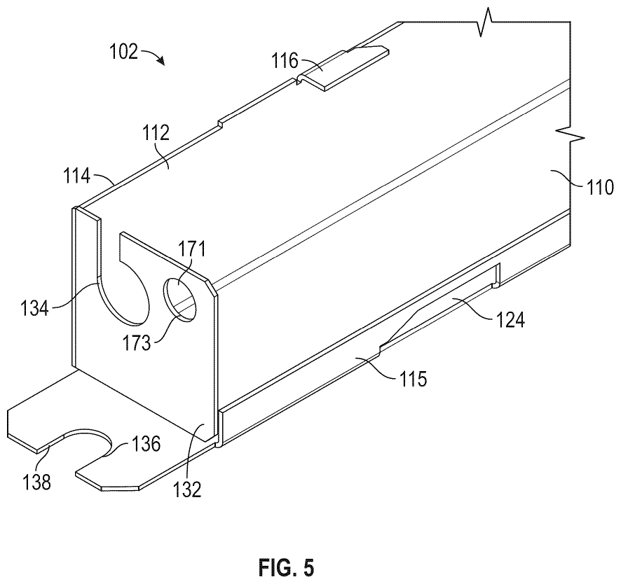

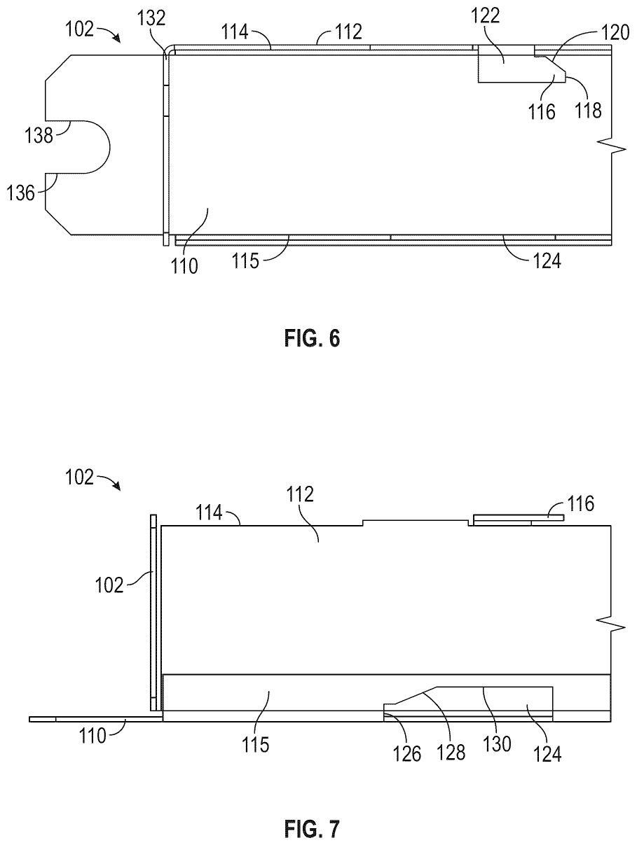

Referring to FIGS. 5-8, the first member 102 includes a first base 110 and a first side 112 extending from the first base 110. In certain embodiments, the first side 112 may extend substantially perpendicular to the first base 110, and the first member 102 may be considered “L-shaped.” However, in other embodiments, the first side 112 may extend at other angles relative to the first base 110 as desired. As illustrated in FIGS. 2 and 4, for example, the first side 112 includes an end 114 opposite from the first base 110, and in certain embodiments, one or more engagement tabs 116 may extend from the end 114. In some embodiments, the engagement tabs 116 may extend substantially perpendicular to the first side 112 and/or substantially parallel to the first base 110, although they need not in other examples. Referring to FIG. 6, the engagement tabs 116 each may include an end 118, an intermediate portion 120, and a main portion 122. The main portion 122 may define a greatest width of the engagement tab 116, and the end 118 may define a minimum width of the engagement tab 116. The intermediate portion 120 may taper between the main portion 122 and the end 118. In certain embodiments, the engagement tabs 116 with the narrower end 118 may facilitate engagement with the second member 104.

Opposite from the first side 112, the first member 102 may include a first flange 115 extending from the first base 110. As best illustrated in FIGS. 5 and 7, the first flange 115 may define one or more locking apertures 124. Referring to FIG. 7, the locking apertures 124 may include an end 126, and intermediate portion 128, and a main portion 130. The end 126 may be a minimum width of the locking aperture 124, the main portion 130 may be a maximum width of the locking aperture 124, and the intermediate portion 128 may transition from the end 126 to the main portion 130. In certain embodiments, the tapered locking apertures 124 may minimize potential gaps between the first member 102 and the second member 104 after engagement.

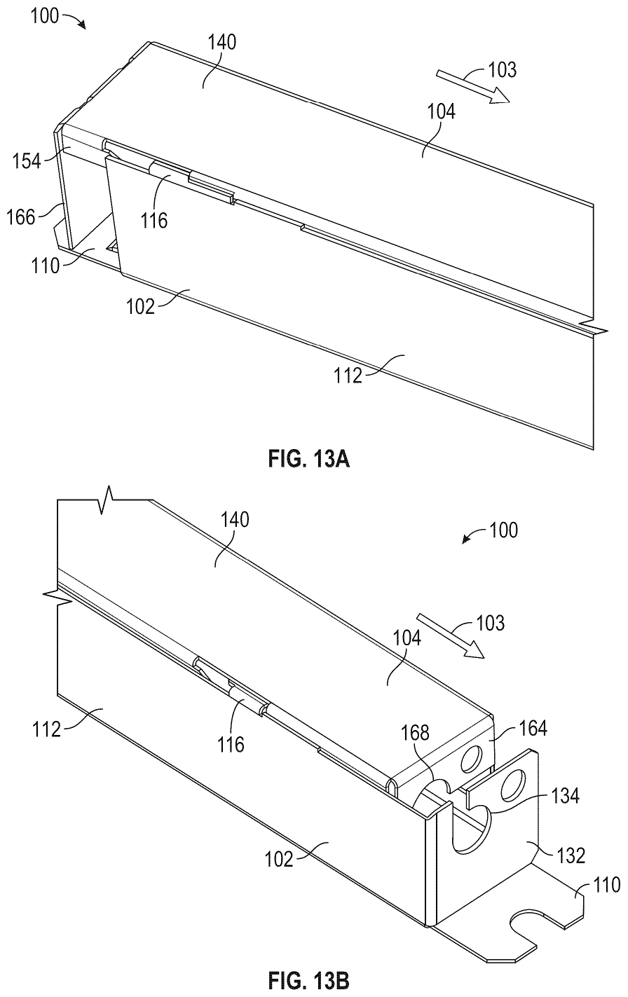

In certain embodiments and as illustrated in FIGS. 5 and 13B, in addition to the first base 110 and the first side 112, the first member 102 may include an end wall 132. In some embodiments, the end wall 132 may partially define a first portion 134 of a wiring aperture 170. As discussed in detail below, the end wall 132 may serve as a stop for the second member 104 when the second member 104 is assembled with the first member 102. The assembled first member 102 and second member 104 may together define the wiring aperture 170 such that the wiring aperture 170 has a closed perimeter.

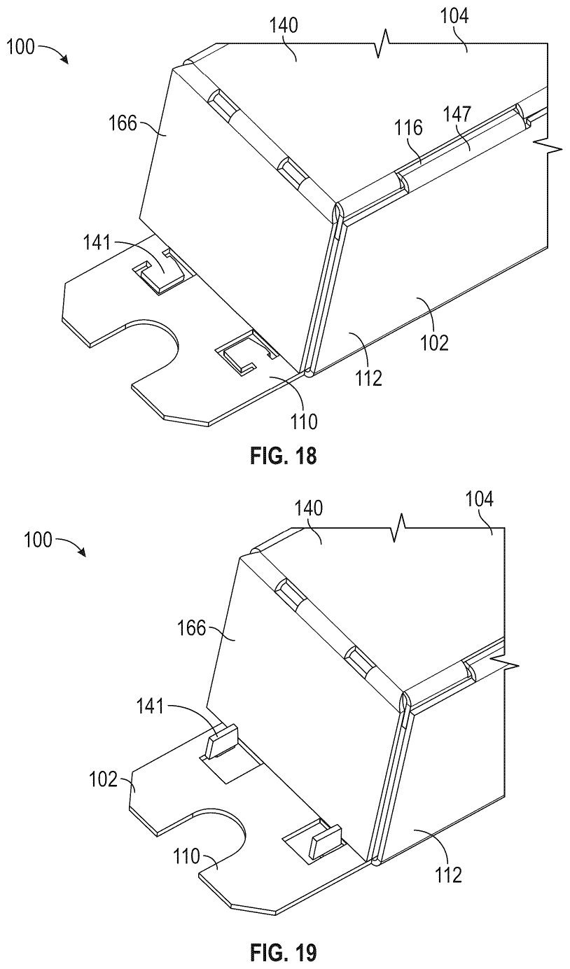

In some embodiments, one or more locking features 141 may be provided on the first base 110. The locking features 141, such as but not limited to locking tabs, may selectively engage the second member 104 when the second member 104 is assembled with the first member 102 to minimize linear movement of the second member 104 relative to the first member 102 (see FIGS. 18 and 19).

Optionally, and as illustrated in FIG. 5, attachment features 136 may be included on the first member 102. The attachment features 136 may be utilized to attach or support the driver enclosure 100 on another object as desired, such as on a light fixture. In the embodiment illustrated, the attachment features 136 are notches 138 configured to receive a mechanical fastener such as a screw, bolt, pin, or the like. However, in other embodiments, other types of attachment features may be utilized as desired.

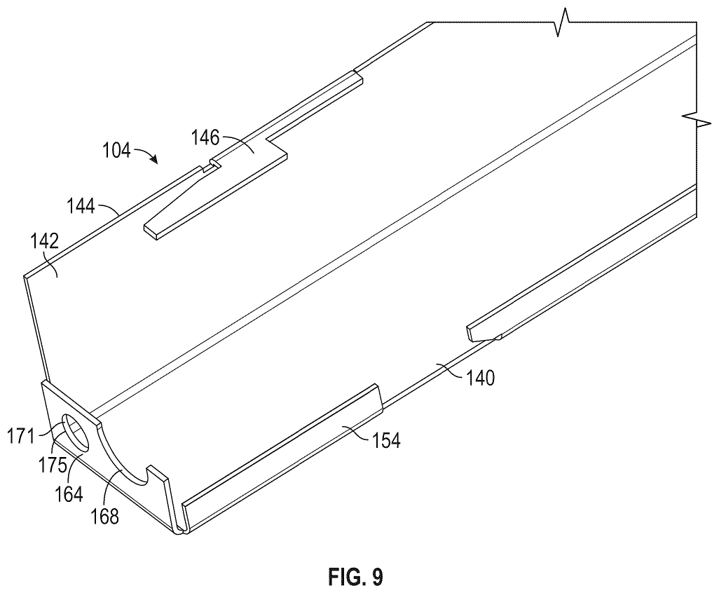

Referring to FIGS. 9-12, the second member 104 includes a second base 140 and a second side 142 extending from the second base 140. The second side 142 may extend from the second base 140 at various angles as desired. In some embodiments, the second side 142 is substantially perpendicular to the second base 140 and similar to the first member 102, the second member 104 may be considered “L-shaped.”

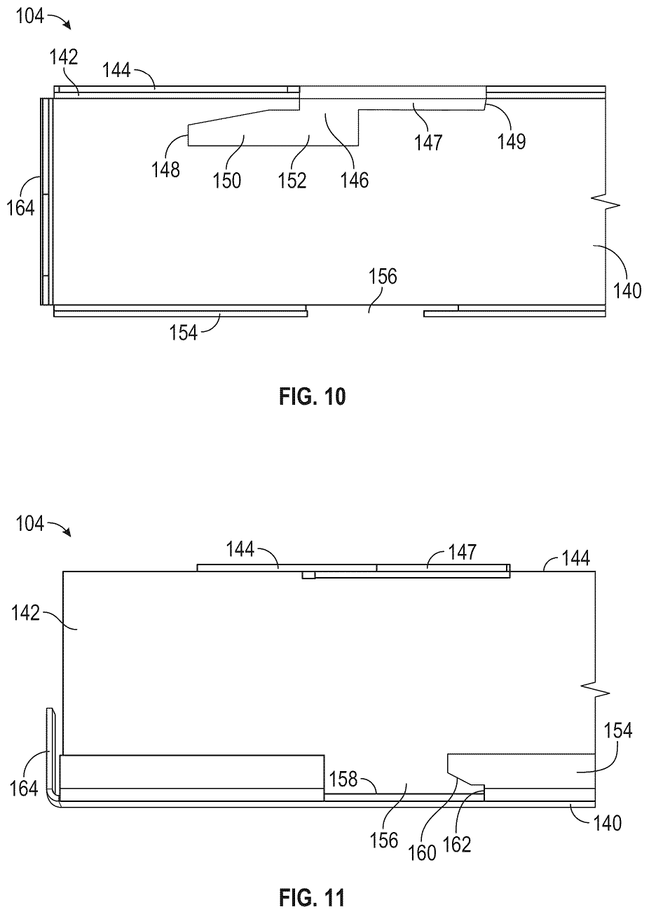

The second side 142 includes an end 144 opposite from the second base 140. In certain embodiments, one or more engagement tabs 146 for engaging the locking apertures 124 on the first member 102 may extend from the end 144. In some embodiments, the engagement tabs 146 may extend substantially perpendicular to the second side 142, although they need not in other examples. Referring to FIG. 10, the engagement tabs 146 each may include an end 148, an intermediate portion 150, and a main portion 152. The main portion 152 may define a greatest width of the engagement tab 146, and the end 148 may define a minimum width of the engagement tab 146. The intermediate portion 150 may taper between the main portion 152 and the end 148. In certain embodiments, the engagement tabs 146 with the narrower end 148 may facilitate engagement with locking apertures 124 of the first member 102.

In certain embodiments, and as illustrated in FIGS. 4 and 10, one or more of the engagement tabs 146 and/or the engagement tabs 116 may include an extension or engagement feature 147. In the embodiment illustrated, the engagement tab 116 of the first member 102 proximate to locking features 141 includes the engagement feature 147, and the engagement tab 146 of the second member 104 proximate to a first end wall 164 includes the engagement feature 147. While the engagement features are illustrated in at least two places, in other embodiments, any number of engagement features 147 may be utilized as desired.

Referring to FIG. 10, the engagement feature 147 includes an end 149, and optionally the end 149 is tapered to facilitate engagement with the first member 102 and/or the second member 104. In certain embodiments, all the engagement tabs may include the engagement feature 147, although they need not in other embodiments. As illustrated in FIG. 18, the engagement feature 147 on the engagement tabs may facilitate engagement and locking between the first member 102 and the second member 104. The engagement features 147 may further cover and/or otherwise obstruct apertures 140 and/or notches 156 in which the engagement tabs are positioned, providing further enclosure of contents within the assembled driver enclosure 100.

Similar to the first member 102, the second member 104 may include a second flange 154 opposite from the second side 142 and extending from the second base 140. One or more locking notches 156 may be defined in the second flange 154 that are configured to interlock with the engagement tabs 116 of the first member 102. Referring to FIG. 11, the locking notches 156 include a main portion 158, an intermediate portion 160, and an end 162. The end 162 may be a narrowest width of the locking notches 156. The tapered locking notches 156 may facilitate initial positioning of the engagement tabs 116 within the locking notches 156 and subsequent interlocking between the engagement tabs 116 and the locking notches 156.

The second member 104 may include the first end wall 164 and a second end wall 166. In certain embodiments, and as illustrated in FIG. 9, the first end wall 164 may define a second portion 168 of the wiring aperture 170. When the first member 102 is assembled with the second member 104, the first end wall 164 may abut the end wall 132, and the first portion 134 and the second portion 168 together define the wiring aperture 170 with the closed perimeter.

Optionally, an aperture 171 may be defined by the first member 102 and the second member 104. Referring to FIG. 5, in some embodiments the first member 102 defines a first portion 173 of the aperture 171, and referring to FIG. 9, the second member 104 defines a second portion 175 of the aperture 171. When assembled, the first portion 173 may align with the second portion 175. When the aperture 171 is included, a fastener such as a screw, bolt, etc. may be used with the aperture 171, which may be used to further secure the first member 102 with the second member 104.

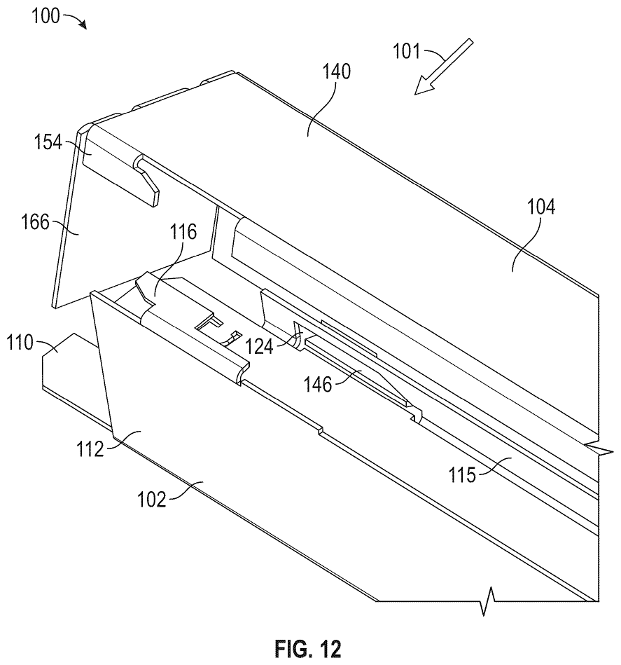

FIGS. 12-19 illustrate a step-by-step progression of assembling the driver enclosure 100 according to various embodiments.

Referring to FIG. 12, in certain embodiments, the driver enclosure 100 is assembled by inserting the engagement tabs 146 of the second member 104 within the locking apertures 124 of the first member 102. Such insertion is represented by arrow 101 in FIG. 12. In such positioning, the engagement tabs 146 may be provided within the main portions 130 of the locking apertures 124. Optionally, the second flange 154 of the second member 104 may be spaced apart from the first side 112 as illustrated in FIG. 12.

Referring to FIGS. 13A-B, when the engagement tabs 146 are inserted within the locking apertures 124, the second flange 154 may be pivoted towards the first side 112 such that the engagement tabs 116 are positioned within the locking notches 156. The tapered engagement tabs 116 may facilitate positioning within the locking notches 156. In such positioning, and as illustrated in FIGS. 13A-B, the engagement tabs 116 may be provided in the main portions 158 of the locking notches 156.

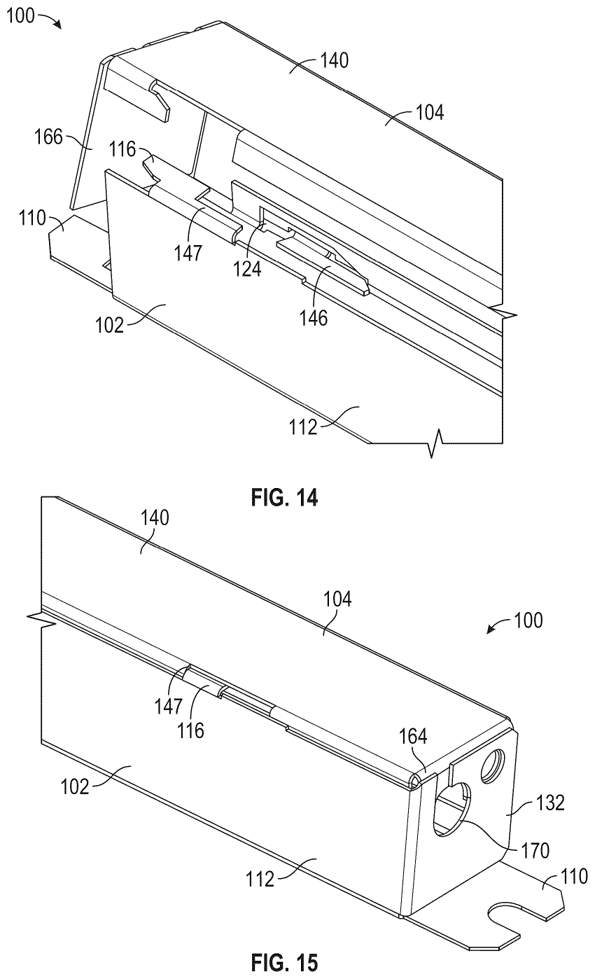

As represented by arrows 103 in FIGS. 13A-B, the second member 104 may be linearly moved relative to the first member 102. As illustrated in FIGS. 14-17, linear movement of the second member 104 relative to the first member 102 may cause the engagement tabs 116 engage the ends 162 of the locking notches 156 and the engagement tabs 146 engage the ends 126 of the locking apertures 124. FIG. 14 illustrates the second member 104 pivoted apart from the first member 102 for ease of viewing engagement between the engagement tabs 146 and the locking apertures 124 after the linear movement.

Referring to FIG. 15, linear movement of the second member 104 relative to the first member 102 may cause the first end wall 164 of the second member 104 to abut the end wall 132 of the first member 102. As illustrated in FIG. 15, such abutment may align the first portion 134 and the second portion 168 such that they together define the wiring aperture 170 with the closed perimeter.

Referring to FIGS. 18 and 19, after linear movement of the second member 104 relative to the first member 102, the locking features 141 may be moved from a stowed position (FIG. 18) to a deployed position (FIG. 19). In the deployed position, the locking features 141 may overlap and/or engage the second end wall 166 of the second member 104. Such overlap may restrict linear movement of the second member 104 relative to the first member 102 and thus inadvertent disassembly of the driver enclosure 100.

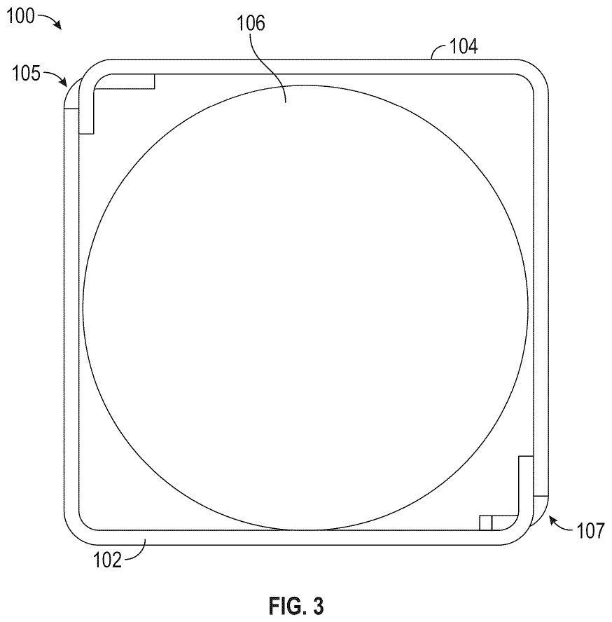

Referring back to FIG. 3, the engagement of the engagement tabs 116 with the locking notches 156 and the engagement of the engagement tabs 146 with the locking apertures 124 forms overlapping regions between the first member 102 and the second member 104 in non-adjacent corners 105, 107 of the driver enclosure 100. The overlapping regions in the non-adjacent corners 105, 107 may optimize the space needed for the overlap, thereby reducing changes in internal volume and/or external widths of the enclosure compared to traditional enclosures.

A collection of exemplary embodiments is provided below, including at least some explicitly enumerated as an “Illustration” providing additional description of a variety of example embodiments in accordance with the concepts described herein. These illustrations are not meant to be mutually exclusive, exhaustive, or restrictive; and the disclosure not limited to these example illustrations but rather encompasses all possible modifications and variations within the scope of the issued claims and their equivalents.

Illustration 1. A battery-driver enclosure comprising a first member and a second member, wherein the first member and the second member together define the battery-driver enclosure, and wherein the first member and the second member overlap at non-adjacent corners of the enclosure.

Illustration 2. The battery-driver enclosure of any preceding or subsequent illustration or combination of illustrations, wherein the first member comprises a first base and a first side extending from the first base, and wherein an end of the first side opposite from the first base comprises an engagement tab configured to engage the second member at one of the non-adjacent corners.

Illustration 3. The battery-driver enclosure of any preceding or subsequent illustration or combination of illustrations, wherein the engagement tab extends perpendicular to the first side.

Illustration 4. The battery-driver enclosure of any preceding or subsequent illustration or combination of illustrations, wherein the engagement tab comprises an end, an intermediate portion, and a main portion, wherein the main portion defines a greatest width of the engagement tab, and wherein the intermediate portion tapers from the main portion to the end.

Illustration 5. The battery-driver enclosure of any preceding or subsequent illustration or combination of illustrations, wherein the second member comprises a second base, a second side extending from the second base, and a second flange extending from the second base opposite from the second side, wherein the second flange comprises a locking notch configured to engage the engagement tab of the first member.

Illustration 6. The battery-driver enclosure of any preceding or subsequent illustration or combination of illustrations, wherein the locking notch comprises a main portion, an intermediate portion, and an end, and wherein the intermediate portion tapers from the main portion to the end.

Illustration 7. The battery-driver enclosure of any preceding or subsequent illustration or combination of illustrations, wherein the first member further comprises a first flange extending from the first base opposite from the first side, wherein a height of the first flange is less than a height of the first side, and wherein the first flange comprises a locking aperture.

Illustration 8. The battery-driver enclosure of any preceding or subsequent illustration or combination of illustrations, wherein the locking aperture comprises an end, an intermediate portion, and a main portion, wherein the main portion defines a maximum width of the locking aperture, and wherein the intermediate portion tapers from the main portion to the end.

Illustration 9. The battery-driver enclosure of any preceding or subsequent illustration or combination of illustrations, wherein the second member comprises a second base and a second side extending from the second base, wherein the second side comprises an engagement feature configured to engage the locking aperture, and wherein the engagement feature is configured to cover the locking aperture.

Illustration 10. The battery-driver enclosure of any preceding or subsequent illustration or combination of illustrations, wherein the engagement feature comprises a tapered end.

Illustration 11. The battery-driver enclosure of any preceding or subsequent illustration or combination of illustrations, wherein, at the non-adjacent corners, an engagement tab is engaged with a locking notch or an engagement aperture, and the engagement tab comprises an engagement feature configured to overlap and obstruct the locking notch or engagement aperture in which the engagement tab is engaged.

Illustration 12. A battery-driver enclosure comprising: a first member comprising a first base, a first side, at least one first locking tab, and at least one locking aperture; and a second member comprising a second base, a second side, at least one second locking tab, and at least one locking notch, wherein the first member and the second member are assembled such that linear movement of the first member relative to the second member engages the at least one first locking tab with the at least one locking notch and engages that at least one second locking tab with the at least one locking aperture.

Illustration 13. The battery-driver enclosure of any preceding or subsequent illustration or combination of illustrations, wherein the at least one first locking tab is engaged with the at least one locking notch at a first corner of the battery-driver enclosure, and wherein the at least one second locking tab is engaged with the at least one locking aperture at a second corner of the battery-driver enclosure, wherein the first corner and the second corner are non-adjacent corners.

Illustration 14. The battery-driver enclosure of any preceding or subsequent illustration or combination of illustrations, wherein the first corner and the second corner are diagonal corners.

Illustration 15. A method of assembling a battery-driver enclosure, the method comprising engaging a first member with a second member to form the battery-driver enclosure and such that the first member and the second member overlap at non-adjacent corners of the battery-driver enclosure.

Illustration 16. The method of any preceding or subsequent illustration or combination of illustrations, wherein engaging the first member with the second member comprises inserting engagement tabs of the second member within locking apertures of the first member and pivoting the second member relative to the first member to position engagement tabs of the first member within locking notches of the second member.

Illustration 17. The method of any preceding or subsequent illustration or combination of illustrations, further comprising linearly moving the second member relative to the first member.

Illustration 18. The method of any preceding or subsequent illustration or combination of illustrations, wherein linearly moving the second member relative to the first member comprises causing engagement portions of the engagement tabs of the second member to overlap the locking apertures of the first member and causing engagement portions of the engagement tabs of the first member to overlap the locking notches of the second member.

Illustration 19. The method of any preceding or subsequent illustration or combination of illustrations, further comprising causing an end wall of the first member to abut an end wall of the second member.

Illustration 20. The method of any preceding or subsequent illustration or combination of illustrations, further comprising moving locking features of the first member from a stowed position to a deployed position, wherein, in the deployed position, the locking features overlap an end wall of the second member.

The various aspects, embodiments, implementations, or features of the described embodiments can be used separately or in any combination. In particular, it should be appreciated that the various elements of concepts from the figures may be combined without departing from the spirit or scope of the invention.

The use of the terms “a” and “an” and “the” and similar referents in the context of describing the invention (especially in the context of the following claims) are to be construed to cover both the singular and the plural, unless otherwise indicated herein or clearly contradicted by context. Directional references such as “up,” “down,” “top,” “bottom,” “left,” “right,” “front,” and “back,” among others, are intended to refer to the orientation as illustrated and described in the figure (or figures) to which the components and directions are referencing. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, or gradients thereof, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention, and does not pose a limitation on the scope of the invention unless otherwise claimed. No language in the specification should be construed as indicating any non-claimed element as essential to the practice of the invention.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, the nearness of completion will be so as to have the same overall result as if absolute and total completion were obtained.

Preferred embodiments of this invention are described herein, including the best mode known to the inventors for carrying out the invention. The invention is susceptible to various modifications and alternative constructions, and certain shown exemplary embodiments thereof are shown in the drawings and have been described above in detail. Variations of those preferred embodiments, within the spirit of the present invention, may become apparent to those of ordinary skill in the art upon reading the foregoing description. The inventors expect skilled artisans to employ such variations as appropriate, and the inventors intend for the invention to be practiced otherwise than as specifically described herein. Accordingly, it should be understood that there is no intention to limit the invention to the specific form or forms disclosed, but on the contrary, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

That which is claimed:

1. A battery-driver enclosure comprising a first member and a second member, wherein the first member and the second member together define the battery-driver enclosure, and wherein the first member and the second member overlap at non-adjacent corners of the enclosure.

2. The battery-driver enclosure of claim 1, wherein the first member comprises a first base and a first side extending from the first base, and wherein an end of the first side opposite from the first base comprises an engagement tab configured to engage the second member at one of the non-adjacent corners.

3. The battery-driver enclosure of claim 2, wherein the engagement tab extends perpendicular to the first side.

4. The battery-driver enclosure of claim 2, wherein the engagement tab comprises an end, an intermediate portion, and a main portion, wherein the main portion defines a greatest width of the engagement tab, and wherein the intermediate portion tapers from the main portion to the end.

5. The battery-driver enclosure of claim 2, wherein the second member comprises a second base, a second side extending from the second base, and a second flange extending from the second base opposite from the second side, wherein the second flange comprises a locking notch configured to engage the engagement tab of the first member.

6. The battery-driver enclosure of claim 5, wherein the locking notch comprises a main portion, an intermediate portion, and an end, and wherein the intermediate portion tapers from the main portion to the end.

7. The battery-driver enclosure of claim 2, wherein the first member further comprises a first flange extending from the first base opposite from the first side, wherein a height of the first flange is less than a height of the first side, and wherein the first flange comprises a locking aperture.

8. The battery-driver enclosure of claim 7, wherein the locking aperture comprises an end, an intermediate portion, and a main portion, wherein the main portion defines a maximum width of the locking aperture, and wherein the intermediate portion tapers from the main portion to the end.

9. The battery-driver enclosure of claim 7, wherein the second member comprises a second base and a second side extending from the second base, wherein the second side comprises an engagement feature configured to engage the locking aperture, and wherein the engagement feature is configured to cover the locking aperture.

10. The battery-driver enclosure of claim 9, wherein the engagement feature comprises a tapered end.

11. The battery-driver enclosure of claim 1, wherein, at the non-adjacent corners, an engagement tab is engaged with a locking notch or an engagement aperture, and the engagement tab comprises an engagement feature configured to overlap and obstruct the locking notch or engagement aperture in which the engagement tab is engaged.

12. A battery-driver enclosure comprising:
a first member comprising a first base, a first side, at least one first locking tab, and at least one locking aperture; and
a second member comprising a second base, a second side, at least one second locking tab, and at least one locking notch,
wherein the first member and the second member are assembled such that linear movement of the first member relative to the second member engages the at least one first locking tab with the at least one locking notch and engages that at least one second locking tab with the at least one locking aperture.

13. The battery-driver enclosure of claim 12, wherein the at least one first locking tab is engaged with the at least one locking notch at a first corner of the battery-driver enclosure, and wherein the at least one second locking tab is engaged with the at least one locking aperture at a second corner of the battery-driver enclosure, wherein the first corner and the second corner are non-adjacent corners.

14. The battery-driver enclosure of claim 13, wherein the first corner and the second corner are diagonal corners.

15. A method of assembling a battery-driver enclosure, the method comprising engaging a first member with a second member to form the battery-driver enclosure and such that the first member and the second member overlap at non-adjacent corners of the battery-driver enclosure.

16. The method of claim 15, wherein engaging the first member with the second member comprises inserting engagement tabs of the second member within locking apertures of the first member and pivoting the second member relative to the first member to position engagement tabs of the first member within locking notches of the second member.

17. The method of claim 16, further comprising linearly moving the second member relative to the first member.

18. The method of claim 17, wherein linearly moving the second member relative to the first member comprises causing engagement portions of the engagement tabs of the second member to overlap the locking apertures of the first member and causing engagement portions of the engagement tabs of the first member to overlap the locking notches of the second member.

19. The method of claim 15, further comprising causing an end wall of the first member to abut an end wall of the second member.

20. The method of claim 15, further comprising moving locking features of the first member from a stowed position to a deployed position, wherein, in the deployed position, the locking features overlap an end wall of the second member.
